(19) United States
(12) Patent Application Publication
(10) Pub. No.: US 2003/0154434 A1
(43) Pub. Date: Aug. 14, 2003

(54) Self testing-and-repairing data buffer and method for operating the same

(76) Inventor: Chien-Tzu Hou, Fremont, CA (US)

Correspondence Address: ROSENBERG, KLEIN & LEE, 3458 ELLICOTT CENTER DRIVE-SUITE 101, ELLICOTT CITY, MD, 21043, US

(21) Appl. No.: 10/068,898

(22) Filed: Feb. 11, 2002

(51) Int. Cl. G01R 31/28

(52) U.S. Cl. 714/734

(57) ABSTRACT

A self testing-and-repairing data buffer and method for operating the same are disclosed. The data buffer comprises a plurality of flip flops, a multiplexer, a test platform, a repair unit, and a buffer rearrange manager. The test platform generates test signals for checking each flip flop. If any damage is found, the repair unit is used to replace the damage flip flops for storing data. The buffer rearrange manager rearranges the address of the damage flip flops to the repair unit so that the data buffer can be operated normally. By the circuit layout and the precise calculation about time delay, the gated clock signal not used currently is used to form the working frequency of the flip flops of the data buffer so as to reduce the power as the IC is inoperative. Furthermore, the area of the data buffer and number of gates are reduced greatly.

### BACKGROUND OF THE INVENTION

1. Field of the Invention

The present invention relates to a self testing-and-repairing data buffer and the method for operating the same, and particularly to one data buffer which can reduce the power as the IC is inoperative, and have an automatic repairing function as faults are found in a test.

2. Description of Related Art

The logic circuits or computers use a large amount data buffers for storing data. Therefore, the data can be sent with elements having a rapid speed, such as center processing unit. In concept of designing logic circuit, each unit in an IC is provided with a synchronous clock. Referring to FIG. 1, the logic circuit of general data buffer is illustrated. In the drawing, a single data buffer 10 is described. The data buffer is formed by a 2-1 mux 11 and a flip-flop (in general, it is a D type flip flop) 12. The multiplexer uses a write-enable signal WE as a selection signal for inputting data for controlling the data writing, outputting data of one selected data buffer, and storing one selecting data into a data buffer.

The input data of flip flop 12 is the output of the multiplexer. The data output end is feedback to one input end of the multiplexer 11. The required working frequency is provided by a clock. With reference to the timing sequence of FIG. 2, when the write-enable signal WE is “1”, the multiplexer 11 inputs a selection input data D to the flip flop 12. After triggering by the clock signal, the input data D is sent and feedback to the multiplexer 11. When the write-enable signal WE is “0”, the multiplexer 11 causes the feedback data into the multiplexer 11. If the write-enable signal WE dose not act further, the flip flop 12 retains the condition of this data until next time the write-enable signal WE is actuated. Therefore, data can be latched for a time period, referring to the time sequence Q in FIG. 2.

However, this circuit has following defects:

1. Even the data buffer 10 is inoperative, the clock signal is still provided to the flip flop 11 until the power is exhausted.

2. After the data buffer is manufactured, it must be tested (scan chain test), in general, at this test, each flip flop 12 is serially connected with another circuit (referring to FIG. 4) for determining whether the data buffer works well. However, this will increase the die area of an IC. Therefore, the cost and test time are increased.

To solve the first problem above, the circuit illustrated in FIG. 1 must be modified. One way is to pass the clock signal through another logic gate 13 (such as an AND gate, etc) and form a gated clock signal. By the logic gate to isolate the gated clock signal, the clock signal actuates a flip flop after a write-enable signal WE is enabled. As shown in the FIG. 3, a logic circuit diagram showing that a logic circuit of a gated clock signal which is used in the conventional data buffer. The gated clock signal fclk is generated by integrating a write-enable signal WE and a clock signal passing through an AND gate 13. With the time sequence of FIG. 2, since the hold time of the clock signal and the write-enable signal WE are different. When the clock signal is transferred to a low level, the write-enable signal WE still retains a high level. Then, after the signal passing through the AND gate 13, the gated clock signal fclk is transferred to a low level. When the clock signal enters into next period, the write-enable signal WE does not convert its condition. After it is converted by the AND gate 13, it generates a pulse. For the data buffer 10, the original data is converted into high level due to the gated clock signal fclk. The data is latched to the flip flop 12, then the small pulse causes the flip flop 12 to latch incorrect value (such as the fault output Q′ of FIG. 2). The original latched data presents an uncertain condition, i.e., the storage function of the data buffer is lost. Another problem is that the set-up time and hold time requirement with respect to the flip-flop 12 might be violated. Thus, the control logic becomes more complicated. This is why does a gated clock signal fclk can not be allowed in general logic circuits and is viewed it disobeys a design rule.

As for the second problem above, to assure an IC's, it must be tested in a test factory. Referring to FIG. 4, a conventional test logic circuit is illustrated. The conventional data buffer 12 is added with a second multiplexer 14. The test input data and normal input data Dare used as inputs of second multiplexers 14. The test mode signal is used to select between normal data or test data of the second multiplexer 14. In test mode, a test input signal is selected for determining whether each flip flop 12 is good. FIG. 4 shows a block diagram of a single bit. For a capacity of 4×64 bit, 64 data buffers as illustrated in FIG. 1 are required. The test input signal in each data buffer must be serially connected to the next data buffer. In other word, 64 extra multiplexers 14 are required. Therefore, the area of the IC is increased

### SUMMARY OF THE INVENTION

Accordingly, the primary object of the present invention is to provide a self testing-and-repairing data buffer and the method for operating the same. The gated clock signal is used to decrease the power as an IC is in operation. The present invention has a self-test function for reducing the cost, and testing time and increasing the yield ratio.

To achieve the object, the present invention provides a self testing-and-repairing data buffer and method for operating the same are disclosed. The data buffer comprises a plurality of flip flops, a multiplexer, a test platform, a repair unit, and a buffer rearrange manager. The test platform generates test signals for checking each flip flop. If any damage is found, the repair unit is used to replace the damage flip flops. The buffer rearrange manager rearranges the address of the damage flip flops to the repair unit so that the data buffer can be operated normally. By the circuit layout and the precise calculation about time delay, the gated clock signal not used currently is used to the flip flops of the data buffer so as to reduce the power as the IC is inoperative. Furthermore, the area of the data buffer is reduced.

The various objects and advantages of the present invention will be more readily understood from the following detailed description when read in conjunction with the appended drawing.

### BRIEF DESCRIPTION OF THE DRAWINGS

FIG. 1 shows the logic block diagram of the data buffer;

FIG. 2 shows the time sequence of the data buffer, which includes the time sequence of conventional design and the present invention;

FIG. 3 is a logic circuit diagram of a gated clock signal applied to a conventional data buffer;

FIG. 4 is a test logic circuit diagram of a conventional data buffer;

FIG. 5 is a logic circuit diagram of the gated clock signal of the data buffer of the present invention;

FIG. 6 is a logic circuit diagram about automatic test and repairing of the data buffer of the present invention;

FIG. 7 shows the operation flow of the data buffer of the present invention; and

FIG. 8 is a schematic view of the network repair structure of the data buffer of the present invention.

### DETAILED DESCRIPTION OF PREFERRED EMBODIMENT

Based on above said defects in the prior art data buffer, the present invention provides a self-testing and repairing data buffer. In the present invention, the clock signal is assured by ways of a circuit layout and the functions of gated clock, self test, fault recovery which is used to retain a normal operation as a fault occurs are used, however, these can not be used in the conventional technology.

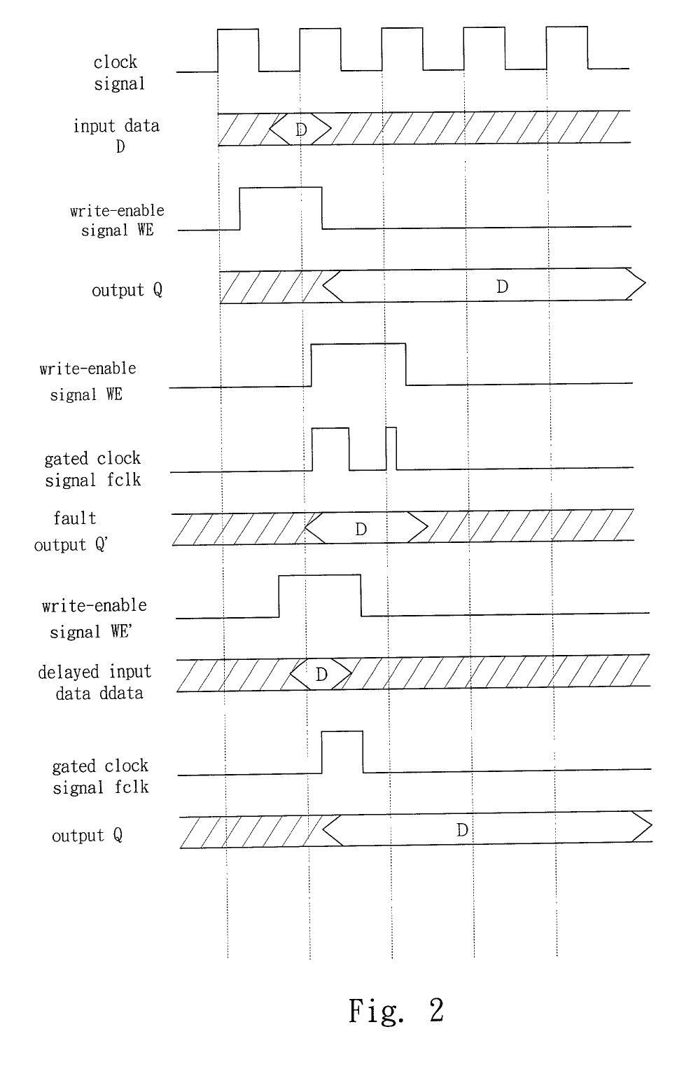

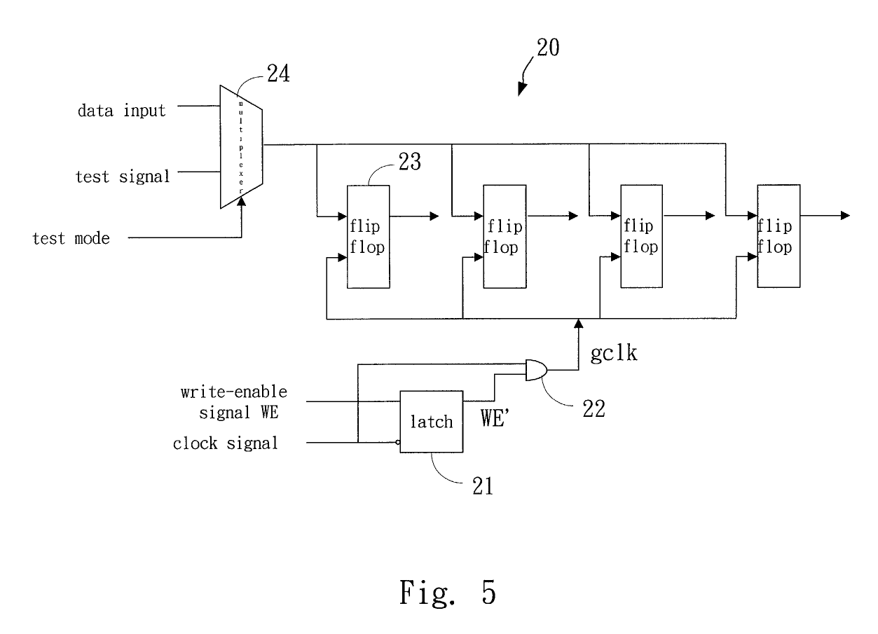

Referring to FIG. 5, the logic circuit of the gated clock signal of the data buffer of the present invention is illustrated. The gated clock signal gclk used in the data buffer 20 of the present invention is generated by a latch 21 and a logic gate 22 (in general, it is an AND gate). In this embodiment, the latch 21 is a transparent latch triggered in a negative edge. In that, when the latch enable is active, the output is equal to the input signal, and when it is non-active, the output signal is retained at the previous output condition. The write enable WE is used as the input of this latch 21. When the clock signal is 0, the latch 21 will be activated to generate an output signal WE′ (referring to FIG. 2). Then the output signal WE′ and the clock signal passes through the logic gate 22 and are formed as a gated clock signal gclk as a working frequency of each flip flop 23.

Referring to the time sequence illustrated in the lower half of FIG. 2, a condition showing that the working condition of the data buffer 20 of the present invention using a gated clock signal gclk. Since the gated clock signal gclk has been delayed for a time period(AND gate delay here), the input signal must be delayed to be synchronous with the gated clock signal gclk to maintain the original set-up and hold time requirement for flip-flops. Therefore, the multiplexer 24 is a time pairing delay multiplexer so that the input of normal data has the same delay time with the gated clock signal gclk. When the input normal data is delayed by the multiplexer 24 and then is formed as a delay data signal ddate, the clock signal and the latch output signal WE′ are integrated by the logic gate 22 to form a gated clock signal gclk which is then sent to the flip flop. After each flip flop 23 receives a gated clock signal gclk, it will be triggered and then the delayed data signal is latched. Since the output signal WE′ will be retained until the next negative edge is triggered, it does not changed during the positive period of the clock signal. Therefore, no clock pulse will be generated. The present invention uses a gated clock signal which is prevented to used in the prior art. This is to say, the data is latched, and much less power is consumed during operation.

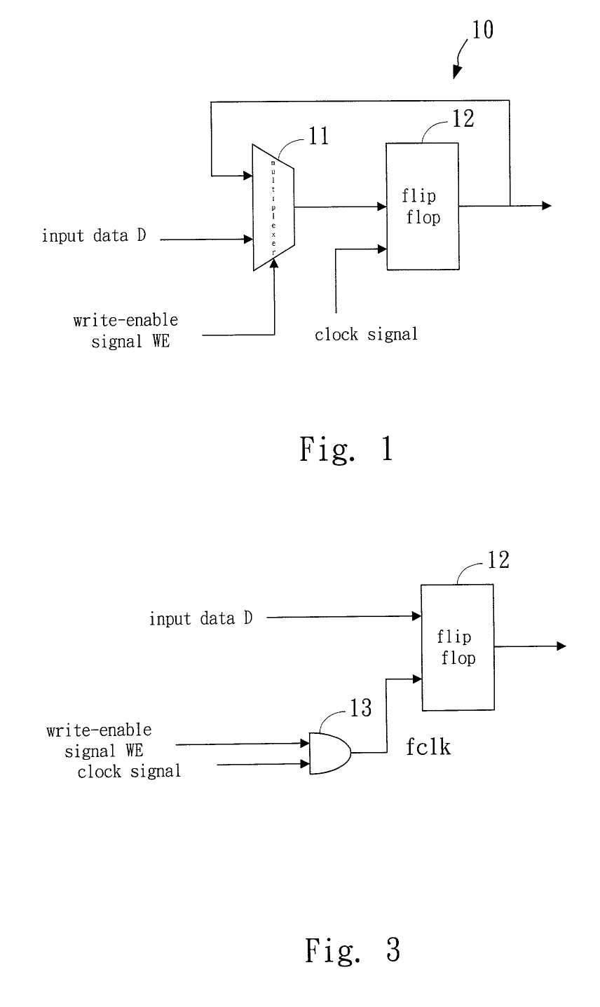

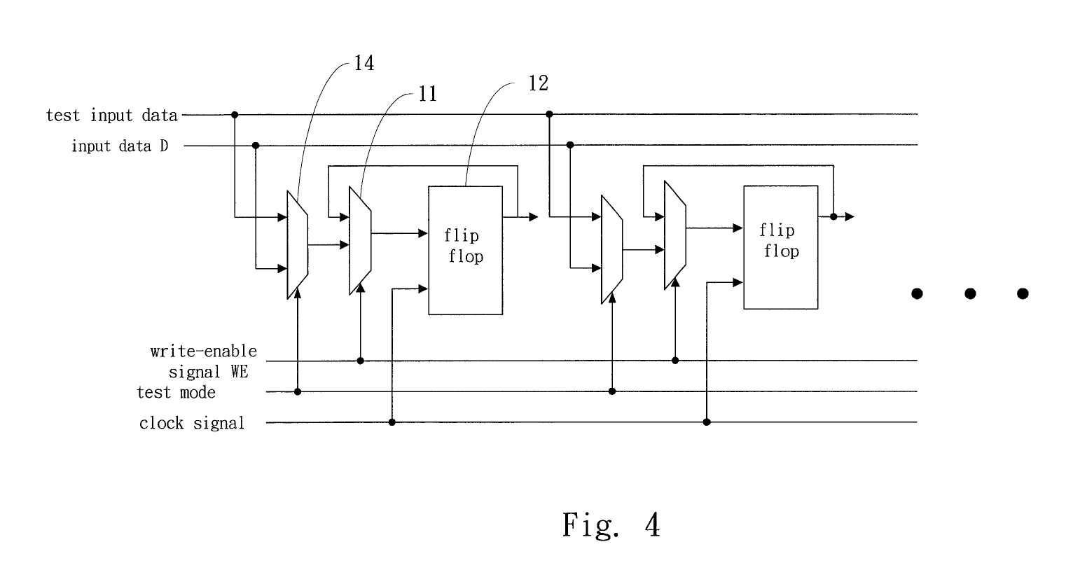

Besides, since the write enable as in FIG. 1 has been changed as an input signal of the latch 21 as in FIG. 5, the selection signal of the multiplexer 24 can be used in other way. In the present invention, to achieve the object of self test and recovery, the conventional external test signal is used as input of the multiplexer 24 (i.e., the multiplexer 11 of FIG. 1), so that the multiplexer 24 selects a normal signal or a test signal input. As a result, an extra second multiplexer 24 as in FIG. 4 for testing can be deleted, and the number of the logic gates and the area for manufacturing an IC can be reduced greatly so as to save some undesired cost.

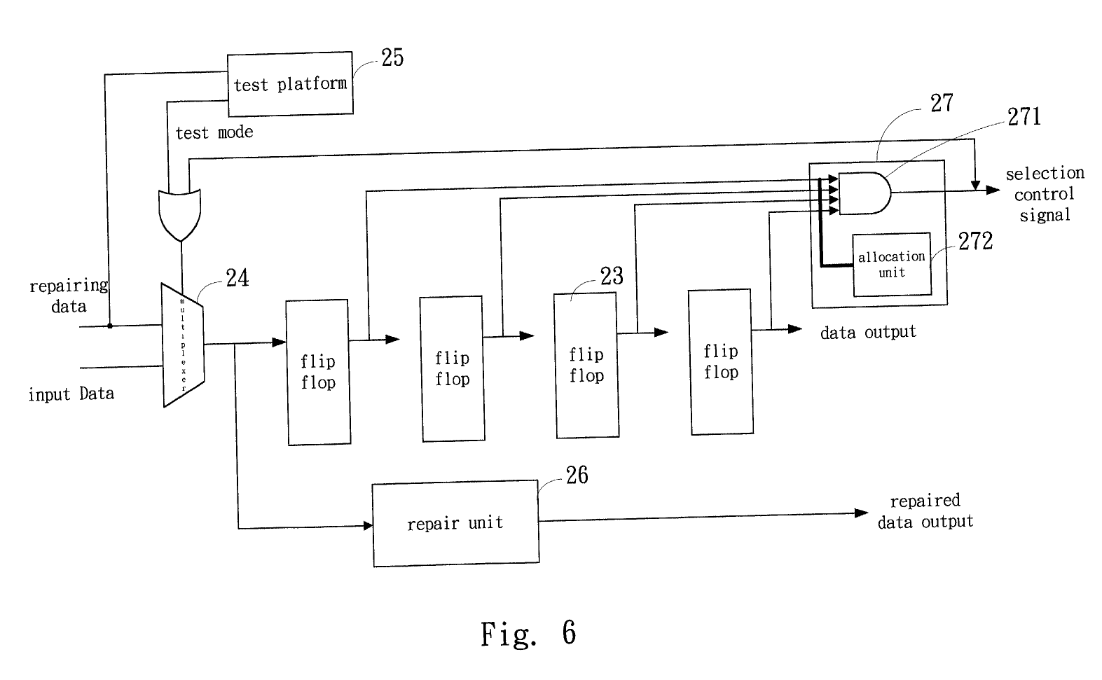

Another feature of the present invention is to provide the function of self-test and automatic recovery, as illustrated in FIG. 6. For brevity, those illustrated FIG. 5 has been neglected from FIG. 6 (i.e., gated clock signal).

Since the present invention has the function of self-test and recovery, after an IC is manufactured, it can save the test steps in a test factory, while most steps of test and recovery are transferred to the system of the user. For example, for a personal computer, after starting up, the actuated process of BIOS is performed firstly. Before transferring control right to the operation system, a test platform 25 is activated to generate a test mode signal for controlling the selection input of a multiplexer, and a set of test bit signals corresponding to the number of the flip flop 23 is generated by the test platform 25. It is a test vector which the least significant bit of the test bit signal is fed back to the most significant bit signal and then are inputted to each flip flop 23 for checking whether the system is in normal condition.

The data buffer 20 comprises the following elements.

A multiplexer 24: Inputs of the multiplexer 24 is controlled by the test mode signal generated by the test platform 25 or the test result of the flip flop for selecting a normal data or a recovery data (or a test bit signal).

A plurality of flip flop 23 serves as data registers. The input of each flip flop 23 is connected to the output of the multiplexer 24. The output of each flip flop 23 is connected to the a buffer allocation manager 27.

A repair cell 26: The repair cell has flip flops the number of which is less than or equal to that of the data buffer 20, and is controlled by the buffer allocation manager 27. When it is determined that at least one flip flop 23 is damaged, it is used to replace the damaged or all the flip flops for output correct input data.

A buffer allocation manager 27: it is installed with a logic gate 271 and an allocation unit 272. The allocation unit 272 serves to record the address of a damaged flip flop 23 in test mode period and allocates the flip flops in the repair unit 26 to the address of the fault the flip flop 23. Therefore, the accessing of the data is replaced by the repair unit 26 partially or completely. The logic gate 271 integrates the outputs of all the flip flops 23 as an input selection control signal of the multiplexer 24.

In the following embodiment, a four bit data buffer is used as an example.

Since the repair unit 26 and each flip flop 23 is made at one IC, the flip flop 23 will has recoverable or unrecoverable defects due to the defects in the manufacturing process. Similarly, the repair unit 26 may occur the same defects. As a result, it is necessary to test these parts. Since the test of the repair unit 26 is identical to that of each flip flop 23 of the data buffer 20, the two can be tested at the same time or separately. In the following, a description about the test of the flip flop 23 in the data buffer 20 is illustrated.

In the test mode, the test platform 25 generates a set of test bit signal with all bits being “1” as the input signals of the flip flops in the repair unit 26 and each flip flop 23 in the data buffer 201. Normally, each flip flop 23 is converted into “1”, i.e., the output of the logic gate 271 (in this embodiment, an AND gate is used) is “1”.

If the output of the logic gate 271 is “0”, it represents that at least one flip flop is stuck at “0” If the output of the logic gate 271 is “1”, it can not assure that all the flip flops 23 are normal, since it is possible that some flip flop 23 is stuck at “1”. Therefore, the test platform 25 regenerates only one “0” bit signal. The test is performed from the minimum effective bit to the maximum effective bit (or along an inverse direction). That is to test whether each flip flop 23 is converted to “0” as receiving a “0” input signal. At this time, the output of the logic gate 271 is retained at “0”. If at “1”, it is assured that at least one flip flop 23 is stuck at “1” condition.

Consequently, depends on the output of the logic gate, 271 can know if there are any flip flop 23 is damaged.

The above test result has the following condition. If the flip flop 23 of the data buffer 20 is damaged, then the repair unit 26 replaces one or all the flip flops 23. If the flip flop 23 of the data buffer 20 is damaged and the repair unit 26 is also damaged, it represent that the data buffer 20 can not be recovered, and thus the data buffer 20 can't be used. If the flip flop 23 of the data buffer 20 is normal, the data buffer 20 can be used normally despite of the condition of the repair unit 26.

About the repair process, the test platform 25 will generate a “0” bit signal to each bit for testing whether each flip flop 23 can change condition to “0” while a “0” input is received. If one of the flip flop 23 is damaged and can not change condition, then the order of the “0” bit can be used to determine the position of the damaged flip flop 23. The allocation unit 272 will record the position of the damaged flip flop 23 and one of the flip flop in the repair unit 26 is re-corresponding to this damaged flip flop 23. When data is written or read out, the control data is input or output from the repair unit 26 so as to maintain the normal operation of the data buffer 20.

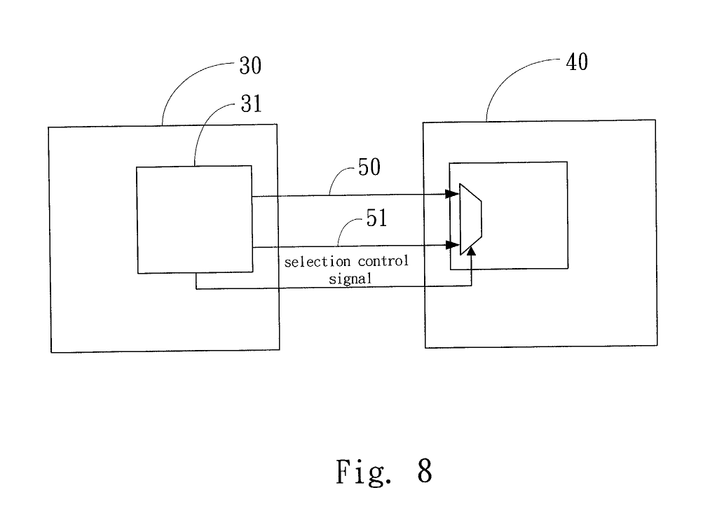

About the data transfer of each unit of the IC, each unit is installed with a data buffer 20, as illustrated in FIG. 8. Assume when the first unit 30 has a fault data buffer 31 after testing or the data input line 50 has fault and thus can not send data, then the flip flop or wire line 50 is replaced by the repair unit. Therefore, the test result of the first unit 30 will be used as the selection control signal of the multiplexer 24 in the second unit 40. Namely, when the first unit 30 or the default connection wire 50 has faults, the second unit 40 only select the data from the repair unit of the first unit 30 through the repair data wire 51. The repair process can be view as a dual parallel data processing unit running with each data block. Only the correct process unit can output its data toward the next stage data block. Similarly, if the second unit 40 is connected with other unit, and any fault occurs, then it is confined that other unit only receives the data from the second unit 40 through a repair data wire. Therefore, the present invention achieve the network repairing structure.

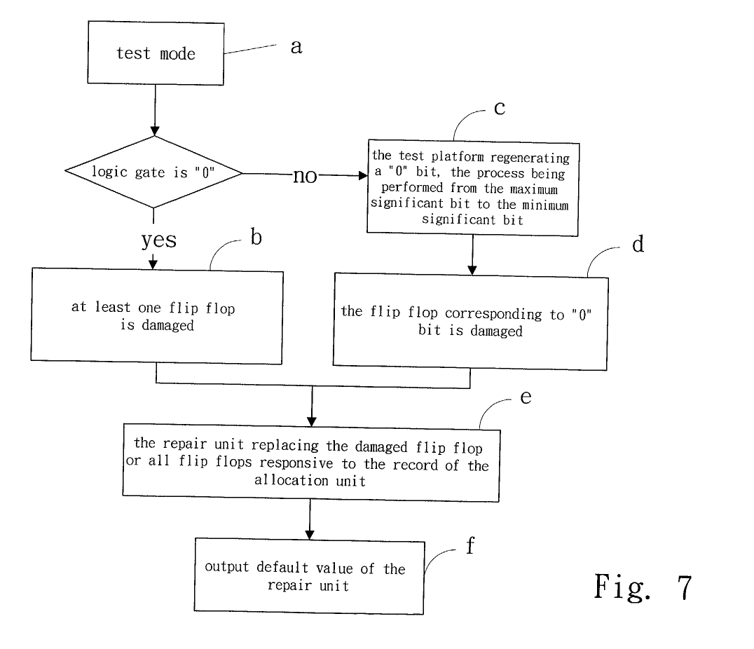

As above stated, the test mode has the following steps (referring to FIG. 7):

Step a: entering into a test mode, the test platform generating a test bit signal with all bit being “1” which are input each flip flop;

Step b: if the flip flop integrated by the logic gate is “0” it representing at least one flip flop is stuck at “0” and can not change state, then the repairing unit replacing the flip flop; In other word, the repair unit should be used as input toward next stage.

Step c: if the flip flop integrated by the logic gate is “1” then the test platform 25 regenerating a “0” bit, the process being performed from the most significant bit to the lest significant bit for determining whether all the flip flop can change state.

Step d: if the output of the flip flop integrated by the logic gate is “1”, then the flip flop corresponding to the address of the bit can not change state normally;

Step e: The repair unit replacing the damaged flip flop or all flip flops responsive to the record of the allocation unit;

Step f: the logic gate integrating all the output of the flip flops as the selection control signal of the multiplexer 24 of the following data buffer so that the input is confined to the output of the repair unit of the previous data buffer;

In summary, in the self-testing and repairing data buffer of the present invention, the gated clock signal not used in the conventional IC design is used so that minimum power is consumed during the operation and the number of the logic gate required in the IC design is reduced. The defects in designing ICs is repaired automatically so as to reduce the test cost and maintain the normal operation of the data buffer.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A self testing-and-repairing data buffer, wherein while a system is boot up and the control is not yet transferred to an operation system, a test platform is activated for testing data buffers and it is repaired as faults occurs, the data buffer comprising:
a multiplexer; input of the multiplexer being controlled by the test mode signal from the test platform or the test result of the flip flop for selecting normal data or the repairing data from the previous stage (or test bit signal);
a plurality of flip flops for registering data, inputs of each flip flop being connected to an output of the multiplexer; outputs of each flip flop being connected to an buffer rearrange manager;
a repair unit being controlled by the buffer rearrange manager; when a flip flop is damaged, it being used to replace that flip flop;
a buffer rearrange manager having an allocation unit for recording addresses of damaged flip flops in the test mode and the addresses of fault flip flops are rearranged in the repair unit so that the assessing of data is replaced partially or wholly by the repair unit.

2. The self testing-and-repairing data buffer as claimed in claim 1, wherein the flip flops has a working frequency from a gated clock signal.

3. The self testing-and-repairing data buffer as claimed in claim 2, wherein the gated clock signal is formed by integrating a latched write enable signal and a clock signal through a logic gate; wherein the latched write enable signal is generated by latch a write enable signal which controls the data writing of the flip flops and the latch enable signal is generated from the negative edge of system clock signal.

4. The self testing-and-repairing data buffer as claimed in claim 3, wherein the logic gate is an AND gate.

5. The self testing-and-repairing data buffer as claimed in claim 1, wherein the flip flops is a D type flip flops.

6. The self testing-and-repairing data buffer as claimed in claim 1, wherein the multiplexer is a time paired delayed multiplexer, thereby, data input is synchronous with the gated clock signal.

7. The self testing-and-repairing data buffer as claimed in claim 1, wherein the test mode signal is the test bit signal corresponding to the number of the flip flops, and the least significant bit is feedback to the most significant bit, which is input to each flip flop for determining whether it is in normal condition.

8. The self testing-and-repairing data buffer as claimed in claim 1, wherein the repair unit is installed with flip flops the number of which is less than or equal to the number of flip flops of the data buffer.

9. The self testing-and-repairing data buffer as claimed in claim 1, wherein the buffer rearrange manager further includes a logic gate for integrating the output values of all flip flops as an input selection signal of the multiplexer.

10. The self testing-and-repairing data buffer as claimed in claim 10, wherein the output of the logic gate is used as a selection control signal of a multiplexer of next data buffer, so that as the previous data buffer or net is damaged, the multiplexer is confined only to select the output data from the previous data buffer for forming a network type repairing.

11. A method for operation a self testing-and-repairing data buffer, wherein the self-test is performed each time the system is started and then a test mode signal is generated, comprising the steps of:
entering into a test mode, the test platform generating a test bit signal with all bit being “1” which are input each flip flop;
if all outputs of the flip flops are “0s” it representing at least one flip flop is stuck at “0” and can not change state, then the repairing unit replacing the flip flop;
if all outputs of the flip flops are “1” then the test platform regenerating a “0” bit, the process being performed from the most significant bit to the least significant bit for determining whether all the flip flop can change state; and
if one of the outputs of the flip flops are “1”, then the flip flop corresponding to the address of the bit can not change state normally;
a repair unit replacing the damaged flip flop or all flip flops responsive to the record of the allocation unit.
